(19) United States
(12) Patent Application Publication
(10) Pub. No.: US 2013/0088251 A1
(43) Pub. Date: Apr. 11, 2013

(54) PROBE CARD AND MANUFACTURING METHOD THEREOF

(71) Applicants: Yong Seok CHOI, Suwon (KR); Dae Hyeong Lee, Suwon (KR); Won Chul Ma, Suwon (KR); Ki Pyo Hong, Suwon (KR)

(72) Inventors: Yong Seok CHOI, Suwon (KR); Dae Hyeong Lee, Suwon (KR); Won Chul Ma, Suwon (KR); Ki Pyo Hong, Suwon (KR)

(73) Assignee: SAMSUNG ELECTRO-MECHANICS CO., LTD.

(21) Appl. No.: 13/614,395

(22) Filed: Sep. 13, 2012

(30) Foreign Application Priority Data
Oct. 6, 2011 (KR) 10-2011-0101856

(51) Int. Cl. G01R 1/04; B29C 65/72

(52) U.S. Cl. 324/756.03; 156/280

(57) ABSTRACT

There are provided a probe substrate and a manufacturing method thereof that may prevent an electrode pad bonded with a probe pin from being released from the probe substrate. The probe card includes: a ceramic substrate having at least one electrode pad on one surface thereof; and a probe pin bonded to the electrode pad, and the electrode pad has a larger dimension than a bonding surface of the probe pin.

### CROSS-REFERENCE TO RELATED APPLICATIONS

This application claims the priority of Korean Patent Application No. 10-2011-0101856 filed on Oct. 6, 2011, in the Korean Intellectual Property Office, the disclosure of which is incorporated herein by reference.

### BACKGROUND OF THE INVENTION

1. Field of the Invention

The present invention relates to a probe card, and more particularly, to a probe card and a manufacturing method thereof that can prevent an electrode pad bonded to a probe pin from being released from a probe substrate.

2. Description of the Related Art

In recent years, as semiconductors have been downsized due to the development of integrated semiconductor circuit technology, semiconductor chip testing devices have been required to have a high degree of precision.

Integrated circuit chips formed on a semiconductor wafer through a wafer fabrication process are classified into fair products and defective products by an electrical die sorting (EDS) process that is performed in a wafer state.

In general, a testing device constituted by a tester that is used for test signal generation and judgment of a test result, a probe station that is used for loading and unloading semiconductor wafers, and a probe card that is used for electrical connection between the semiconductor wafer and the tester, is mainly used for the EDS.

Among these elements, as the probe card, a type of card in which the probe pin is bonded to a ceramic substrate, the ceramic substrate being fabricated by laminating a circuit pattern, an electrode pattern, a via electrode, and the like on a ceramic green sheet, which are thereafter fired, is primarily used.

As the ceramic substrate, a high temperature co-fired ceramic substrate is primarily used, but a low temperature co-fired ceramic substrate has also tended to be used in recent years.

However, when the low temperature co-fired ceramic substrate is used, bonding force between the electrode pad formed on the substrate and the substrate is weak, as compared with the high temperature co-fired ceramic substrate.

Such a defect may cause a problem in which, during a process of re-removing the probe pin as needed after the probe pin is attached to the ceramic substrate, rather than only a probe pin of the electrode pad having the probe pin attached thereto being released from the substrate, the electrode pad itself is separated therefrom.

### SUMMARY OF THE INVENTION

An aspect of the present invention provides a probe card and a manufacturing method thereof that can ensure bonding force between an electrode pad formed on a ceramic substrate and the substrate.

According to an aspect of the present invention, there is provided a probe card, including: a ceramic substrate having at least one electrode pad on one surface thereof; and a probe pin bonded to the electrode pad, and the electrode pad has a larger dimension than a bonding surface of the probe pin.

The ceramic substrate may further include a plurality of conductive vias and a circuit pattern electrically connecting the conductive vias and the electrode pad.

The probe pin may be bonded to the center of the top surface of the electrode pad exposed to the outside of the ceramic substrate.

The ceramic substrate may further include a protective insulation layer configured to cover a portion of the electrode pad.

The protective insulation layer may include a through-hole formed in a portion thereof bonded to the probe pin.

The protective insulation layer may be formed of polyimide.

According to another aspect of the present invention, there is provided a manufacturing method of a probe card, including: providing a ceramic substrate where an electrode pad is formed in a larger dimension than a bonding surface of a probe pin; and bonding the probe pin onto the electrode pad.

The method may further include forming a protective insulation layer on the top of the ceramic substrate, after the forming of the electrode pad.

In the forming of the protective insulation layer, the protective insulation layer may include a through-hole formed in a portion thereof bonded to the probe pin.

In the forming of the protective insulation layer, the protective insulation layer may be formed while covering a portion of the electrode pad on the circumference thereof.

In the forming of the protective insulation layer, the protective insulation layer may be formed of polyimide.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically illustrating a probe card according to an embodiment of the present invention;

FIG. 2 is a cross-sectional view taken along line A-A of FIG. 1;

FIG. 3 is a plan view illustrating a probe substrate of FIG. 1; and

FIGS. 4A through 4C are cross-sectional views for each process to describe a manufacturing method of a probe substrate according to an embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

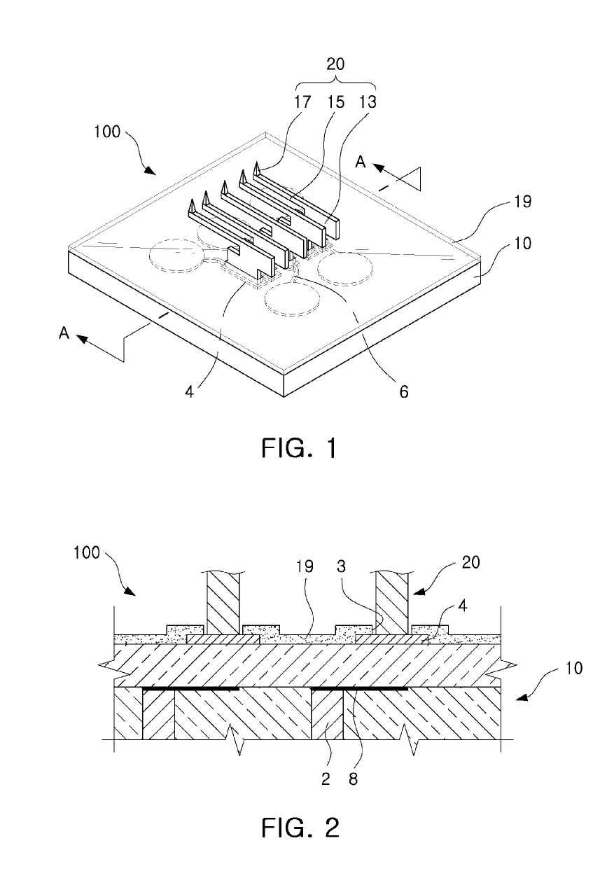

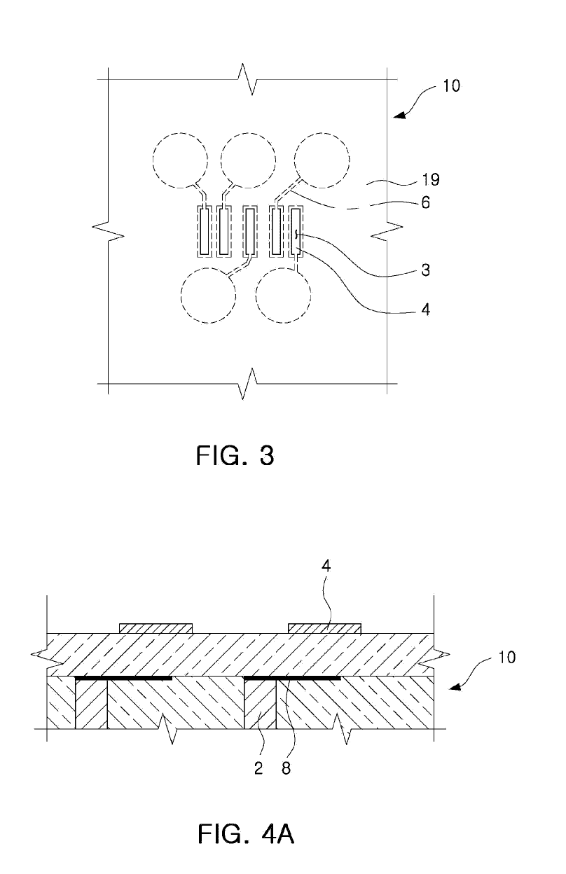

FIG. 1 is a perspective view schematically illustrating a probe card according to an embodiment of the present invention and FIG. 2 is a cross-sectional view taken along line A-A of FIG. 1. FIG. 3 is a plan view illustrating a probe substrate of FIG. 1.

Referring to FIGS. 1 through 3, the probe card 100 according to the embodiment may include a probe substrate 10 and a probe pin 20.

The probe substrate 10 as a ceramic substrate has at least one electrode pad 4 on one surface thereof.

The probe substrate 10 (hereinafter, the probe substrate and the ceramic substrate are used and described together for convenience of description, but both terms indicate the same substrate component) may be manufactured by laminating a plurality of ceramic green sheets and firing the laminated ceramic green sheets.

In the ceramic substrate 10, a plurality of ceramic layers may be formed by the ceramic green sheets, and wiring patterns 8 and conductive vias 2 vertically connecting the wiring patterns 8 may be formed in the respective ceramic layers.

A circuit pattern 6 and a plurality of electrode pads 4 are formed on one surface of the ceramic substrate 10.

The circuit pattern 6 may electrically connect the conductive via 2 connected to the inside of the ceramic substrate 10 to the electrode pad 4 placed on one surface of the ceramic substrate 10.

The electrode pads 4 may be placed to be spaced apart from each other by a predetermined distance on one surface of the ceramic substrate 10. A probe pin 20 to be described below is bonded to the electrode pad 4 to be physically and electrically connected.

Herein, the electrode pad 4 is an added component as the probe substrate 10 according to the present embodiment is configured by the ceramic substrate. As described above, the ceramic substrate 10 is manufactured by laminating the wiring pattern 8 and a via electrode (not illustrated) on the ceramic green sheet and thereafter, firing them. However, the ceramic green sheet may be contracted while the ceramic substrate 10 is fired, and as a result, the position of the via electrode is partially changed. Therefore, the via electrode of the ceramic substrate 10 of which firing is completed is low in terms of precision of a placement position.

Therefore, the ceramic substrate 10 according to the present embodiment has a separate electrode pad 4 on one surface thereof and electrically connects the via electrode and the electrode pad 4 by using the circuit pattern 6.

Meanwhile, the electrode pad 4 and the circuit pattern 6 may be used to extend distances among the probe pins 20 or rearrange the probe pins 20 so as to easily attach the probe pins 20 with respect to the via electrodes 2 placed to be narrowly spaced apart from one another on the ceramic substrate 10.

Meanwhile, the ceramic substrate 10 may be a low temperature co-fired ceramic (LTCC) substrate. In the case of a high temperature co-fired ceramic (HTCC) substrate, since firing is performed at approximately 1500 to 1700° C., W, Mo, and the like are used as conductive materials. Therefore, a process cost is increased and it is difficult to implement size precision for a large-dimension precision pattern.

However, a low temperature co-fired ceramic (LTCC) substrate is limited in terms of the use thereof due to bonding force of the electrode pad 4 being lower than the high temperature co-fired ceramic (HTCC) substrate.

In order to improve this limit according to the present embodiment, dimensions of the electrode pad 4 formed on the ceramic substrate 10 may be greater than a cross section of a bonding unit 13 of the probe pin 20 to be described below.

In greater detail, based on a bonding surface on which the bonding unit 13 of the probe pin 20 is bonded to the electrode pad 4, the electrode pad 4 according to the present embodiment may have an area larger than that of the bonding surface.

A bottom surface of the bonding unit 13 of the probe pin 20 may be placed in the center of the electrode pad 4 and bonded thereto. Therefore, when the bonding unit 13 of the probe pin 20 is bonded to the electrode pad 4, the electrode pad 4 may be partially exposed around the bonding unit 13, as illustrated in FIG. 1.

This configuration may be useful in the application thereof while the probe pin 20 is replaced because a problem may occur in the probe pin 20 being used. This will be described in detail below.

As a process of removing the probe pin 20 which has already been bonded onto the electrode pad 4, a method of separating the probe pin 20 from the electrode pad 4 by pressing the probe pin 20 on the side thereof is generally used.

However, since the probe pin 20 and the electrode pad 4 are metal-bound to each other, bonding force between the probe pin 20 and the electrode pad 4 is generally larger than bonding force between the electrode pad 4 and the ceramic substrate 10.

As a result, while the probe pin 20 is pressed, the electrode pad 4 may be separated, together with the probe pin 20, from the ceramic substrate 10, without separating the probe pin 20 from the electrode pad 4 as intended.

However, since the electrode pad 4 according to the embodiment is attached to the ceramic substrate 10, having relatively larger dimensions as described above, the bonding force between the electrode pad 4 and the ceramic substrate 10 may be increased.

In the electrode pad 4 according to the embodiment, the probe pin 20 is bonded to the center of the electrode pad 4. Therefore, when force is applied to the side of the probe pin 20, force is applied to the center of the electrode pad 4 rather than to the border of the electrode pad 4, thereby preventing a release of the electrode pad 4 from starting at the border thereof.

Likewise, since the bonding force between the electrode pad 4 according to the embodiment of the present invention and the ceramic substrate 10 may be improved, the low temperature co-fired ceramic substrate may easily be used as the probe substrate 10.

The electrode pad 4 may be formed of the conductive material. In detail, silver (Ag), gold (Au), palladium (Pd), platinum (Pt), rhodium (Rh), copper (Cu), titanium (Ti), tungsten (W), molybdenum (Mo), nickel (Ni), and alloys thereof may be used as materials therefor. However, the present invention is not limited thereto.

The electrode pad 4 may be formed through a circuit pattern forming process of the generally used substrate, but is not limited thereto and the circuit pattern forming process maybe used in various methods such as plating, a screen printing method, and the like.

The ceramic substrate 10 according to the embodiment includes a protective insulation layer 19. The protective insulation layer 19 is placed on the top of the ceramic substrate 10 to protect one surface of the ceramic substrate 10.

The protective insulation layer 19 is configured to cover a portion of the top of the electrode pad 4. That is, a through-hole 3 is formed in a portion of the protective insulation layer 19 corresponding to the electrode pad 4, and the through-hole 3 is configured to be smaller than the dimension of the electrode pad 4. In more detail, the through-hole 3 is configured to have a size corresponding to the bonding surface of the bonding unit 13 of the probe pin 20.

Therefore, the electrode pad 4 according to the embodiment of the invention maybe more rigidly attached to the ceramic substrate 10 by the protective insulation layer 19. As the protective insulation layer 19 is configured to cover a portion of the electrode pad 4, the protective insulation layer 19 supports the electrode pad 4 downward through the bonding force with the ceramic substrate 10 even in the case that force is applied to the probe pin 20. Therefore, the electrode pad 4 may not easily be released from the ceramic substrate 10.

To this end, the protective insulation layer 19 according to the embodiment may be formed of polyimide. Since polyimide has relatively high heat-resistance and is relatively low in terms of property variations at high temperatures, when heat is applied to a bonding pad in a process such as bonding the probe pin 20, the protective insulation layer 19 may be prevented from being damaged by using polyimide for the protective insulation layer 19.

When polyimide is used, the thickness of the protective insulation layer 19 may be relatively small, and as a result, the thickness of the ceramic substrate 10 is not also significantly increased.

The probe pin 20, provided as a cantilever type pin may include the bonding unit 13, a body portion 15, and a contact portion 17. The probe pin 20 may be manufactured by using a minute thin-plate technique applied in semiconductor fabrication.

The bonding unit 13 has a shape of a quadrangular plate, one end of the bonding unit 13 is bonded to the electrode pad 4 of the ceramic substrate 10 to be electrically connected, and the other end of the bonding unit 13 may be connected with one end of the body portion 15.

The body portion 15 may have a cantilever structure and the other end of the body portion 15 may be connected with one end of the contact portion 17.

The contact portion 17 may be formed vertically to the other end of the body portion 15 and the other end of the contact portion 17 may include a contact tip 19 which may be in contact with a tested object (not illustrated).

Meanwhile, in the present embodiment, the probe pin 20 is the cantilever type pin, but is not limited thereto, and may be transformed to have various forms such as a linear form, which are bonded vertically.

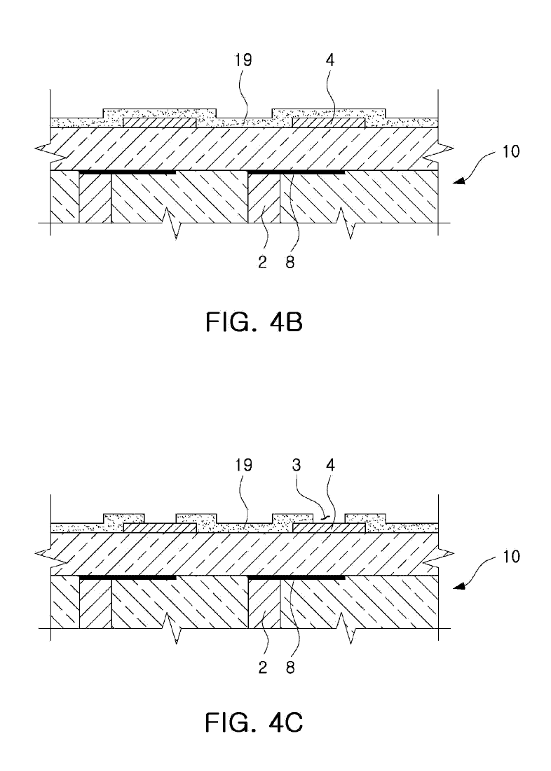

Hereinafter, a manufacturing method of the probe substrate 10 according to an embodiment of the present invention will be described. FIGS. 4A through 4C are cross-sectional views for each process to describe a manufacturing method of a probe substrate according to an embodiment of the present invention.

First, as illustrated in FIG. 4A, a ceramic substrate 10 in which a plurality of ceramic layers are laminated and fired is provided.

The wiring pattern 8, the conductive via 2, the via electrode (not illustrated), and the like may be formed on the plurality of ceramic layers constituting the ceramic substrate 10. The circuit pattern 6 of FIG. 1 and at least one electrode pad 4 may be formed on one surface of the ceramic substrate 10, that is, the top of the ceramic substrate 10.

Herein, the electrode pad 4 may be electrically connected with the via electrode (not illustrated) by the circuit pattern 6.

Meanwhile, as described above, the ceramic substrate 10 may be the low temperature co-fired ceramic substrate. The low temperature co-fired ceramic substrate 10 may be formed by providing the ceramic green sheet by a known method skilled in the art such as a doctor blade process, and thereafter, forming the conductive via 2 and the wiring pattern 8 on each ceramic green sheet, and laminating and firing them. In this case, the firing process may be performed at a temperature within the range of approximately 700 to 900° C.

Next, as illustrated in FIG. 4B, forming the protective insulation layer 19 on the ceramic substrate 10 is performed. The protective insulation layer 19 may be formed by a general method of forming an insulating layer on the substrate. As described above, the protective insulation layer 19 according to the present embodiment may be formed of polyimide.

Subsequently, as illustrated in FIG. 4C, forming the through-hole 3 in the protective insulation layer 19 by using a mask is performed. The through-hole 3 may be formed to have a size and a shape corresponding to the dimension of the bonding surface of the probe pin 20 as described above.

When the probe substrate 10 according to the embodiment of the invention is completed through the above process, the probe pin 20 is attached to the top of the electrode pad 4 to complete the probe card 100 according to the embodiment of the invention illustrated in FIG. 1. In this case, the probe pin 20 may penetrate the through-hole 3 of the protective insulation layer 19 and may be bonded to the electrode pad 4.

As set forth above, in the probe card according to the embodiments of the present invention, since the electrode pad is attached to the ceramic substrate through a relatively large dimension, the bonding force between the electrode pad and the ceramic substrate may be increased.

Since the probe pin is bonded to the center of the electrode pad, when force is applied to the side of the probe pin, force is not applied to a border of the electrode pad, but is applied to the inside of the electrode pad, thereby preventing a release of an electrode pad from starting on the border thereof or preventing the electrode pad from being released together with the probe pin from the substrate.

In addition, since the protective insulation layer is formed to cover a portion of the electrode pad, the bonding force between the electrode pad and the ceramic substrate may be further reinforced.

As a result, even in the case that a defect occurs in the probe pin being used, the probe pin may easily be replaced, and as the probe substrate, the low temperature co-fired ceramic substrate may easily be used.

Meanwhile, the probe card and the manufacturing method thereof according to embodiments of the present invention are not limited to the aforementioned embodiments and may be variously implemented.

Further, although the case in which the probe card is formed by using the ceramic substrate in the embodiment has been described as an example, the present invention is not limited thereto, and the probe card may be widely adopted as long as it is a probe card to which the probe pin is bonded.

While the present invention has been shown and described in connection with the embodiments, it will be apparent to those skilled in the art that modifications and variations can be made without departing from the spirit and scope of the invention as defined by the appended claims.

What is claimed is:

1. A probe card, comprising:
a ceramic substrate having at least one electrode pad on one surface thereof; and
a probe pin bonded to the electrode pad,
the electrode pad having a larger dimension than a bonding surface of the probe pin.

2. The probe card of claim 1, wherein the ceramic substrate further includes a plurality of conductive vias and a circuit pattern electrically connecting the conductive vias and the electrode pad.

3. The probe card of claim 1, wherein the probe pin is bonded to the center of the top surface of the electrode pad exposed to the outside of the ceramic substrate.

4. The probe card of claim 3, wherein the ceramic substrate further includes a protective insulation layer configured to cover a portion of the electrode pad.

5. The probe card of claim 4, wherein the protective insulation layer includes a through-hole formed in a portion thereof bonded to the probe pin.

6. The probe card of claim 4, wherein the protective insulation layer is formed of polyimide.

7. A manufacturing method of a probe card, comprising:
providing a ceramic substrate where an electrode pad is formed in a larger dimension than a bonding surface of a probe pin; and
bonding the probe pin onto the electrode pad.

8. The method of claim 7, further comprising, after the forming of the electrode pad, forming a protective insulation layer on the top of the ceramic substrate.

9. The method of claim 8, wherein in the forming of the protective insulation layer, the protective insulation layer includes a through-hole formed in a portion thereof bonded to the probe pin.

10. The method of claim 8, wherein in the forming of the protective insulation layer, the protective insulation layer is formed while covering a portion of the electrode pad on the circumference of the electrode pad.

11. The method of claim 8, wherein in the forming of the protective insulation layer, the protective insulation layer is formed of polyimide.
